(19) United States
(12) Patent Application Publication
(10) Pub. No.: US 2006/0137968 A1
(43) Pub. Date: Jun. 29, 2006

(54) Oscillating shielded cylindrical target assemblies and their methods of use

(76) Inventor: Klaus Hartig, Avoca, WI (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 11/311,526

(22) Filed: Dec. 19, 2005

Related U.S. Application Data
(60) Provisional application No. 60/639,387, filed on Dec. 27, 2004.

(51) Int. Cl. C23C 14/32; C23C 14/00

(52) U.S. Cl. 204/192.1; 204/298.12

(57) ABSTRACT

The present invention relates to an oscillating shielded cylindrical target assembly comprising a cylindrical target, a motor assembly adapted to oscillate the cylindrical target, a shield, and a magnet assembly. Embodiments of the present invention also include a cylindrical target that has an outer surface containing a plurality of divided sections; the sections being disposed lengthwise around the target to form strips running lengthwise across the target. Each section includes a single sputtering material, such as silver, titanium, or niobium, that is intended to be applied as a separate coating on a substrate, such as glass.

### RELATED APPLICATION

The present application claims priority to U.S. provisional patent application 60/639,387, filed Dec. 27, 2004, the entire disclosure of which is incorporated herein by reference.

### FIELD OF THE INVENTION

The present invention relates to an oscillating shielded cylindrical target assembly comprising a cylindrical target, a motor assembly adapted to oscillate the cylindrical target, a shield, and a magnet assembly. Moreover, various embodiments of the present invention relate to an oscillating shielded cylindrical target having a multi-sectional cylindrical target adapted for oscillation.

### BACKGROUND OF THE INVENTION

Cylindrical targets are widely used in magnetron sputtering systems for depositing thin coatings and films on substrates. A magnetron sputtering process normally is conducted in an evacuated chamber containing a small quantity of an ionizable gas such as argon. A voltage applied to the cylindrical target, with respect to either the vacuum chamber enclosure or a separate anode, creates a plasma that is localized along a sputtering zone of the target by stationary magnets positioned within the target. The cylindrical target comprising the material to be sputtered is bombarded by the ions present within the plasma causing atoms of the target material to be dislodged and subsequently deposited as a film on the substrate to be coated. The substrate being coated is generally moved, either continuously or intermittently, relative to the target in a direction transverse to the longitudinal axis of the target. It will be appreciated that the sputtering zone is created by the magnets located along substantially the entire length of the cylindrical sputtering target and extending only a small circumferential (radial) distance around it.

In a process such as the one previously described, it is generally advantageous to rotate the cylindrical target. The rotation of the target provides several benefits. First, the rotation of the cylindrical target provides for a distributed consumption of the target over a much larger surface area than if the target were to remain stationary. More specifically, the rotation of the cylindrical target assists in the prevention of a “race track” pattern, which may be etched into a stationary planar target when utilizing a magnetron sputtering process. Correspondingly, more of the target is utilized and an enhanced uniform consumption of the cylindrical target is achieved.

Another benefit of rotating the target is that rotation assists in the prevention and removal of undesirable film build-up and condensation. The deposition and build-up of coating materials upon the surfaces of the target and other surfaces within the system's vacuum chamber cause lost time and increased cost in the clean-up of unwanted sputtering material. Furthermore, the deposition and build-up of coating material on surface areas of the magnetron sputtering system can result in damage to the various components of the system due to arcing. Arcing is undesirable since it normally causes an overload to the power supply that creates the plasma, thereby disturbing the generation of plasma causing non-uniform coating, halting production and/or causing damage to equipment. Finally, overcoating, especially the deposit of oxidized sputtering materials upon a target, such as titanium oxide on a titanium target, can contribute to a nonuniform consumption of the target and a further exaggeration of consumption patterns on the target. The rotation of the target thus assists in the prevention of multiple problems associated with “overcoating” and subsequent “arcing” that accompany the deposit of sputtering material on areas not intended to be sputtered.

Although conventional rotating cylindrical targets provide many advantages over the previously utilized stationary planar targets, many disadvantages remain. For example, the existing cylindrical targets typically provide a surface containing only a single coating material. Thus, when multiple coatings on a single substrate are desired, current targets having a single coating material thereon require: (1) the changing of the entire target in a single chamber; (2) multiple cylindrical target assemblies within a single vacuum chamber; and/or (3) multiple cylindrical targets each with an associated vacuum chamber. Each of these options has an associated weakness. Changing the entire target in a single assembly is far too time consuming and laborious, for example, in the commercial production of coated glass. Moreover, it may be difficult to change the target in a sputtering chamber without losing control over the established sputtering atmosphere in the chamber. In order to provide multiple targets within a single chamber, it may be necessary to provide barriers between each target. When each target is housed in a separate chamber, space costs, such as repetitive cleaning costs, are incurred. Regardless of the method used, the ultimate result is wasted time and/or expense when attempting to apply multiple film coatings to a substrate using targets having a single coating material.

### SUMMARY OF THE INVENTION

Embodiments of the present invention retain the cylindrical target assemblies' advantages of dispersed consumption and self-cleaning. In addition, the present invention addresses the previously mentioned disadvantages of prior art cylindrical rotatable target assemblies.

Generally, the present invention relates to an oscillating shielded cylindrical target assembly comprising a cylindrical target, a motor assembly adapted for oscillating the cylindrical target, an optional shield assembly, and a magnet assembly. Embodiments of the present invention include a cylindrical target that has an outer surface containing a plurality of divided sections; the sections being disposed lengthwise around the target to form strips running lengthwise across the target. Each section includes a single sputtering material, such as silver, titanium, or niobium, that is intended to be applied as a separate coating on a substrate, such as glass. As a result, for example, a single cylindrical target could be made up of four sections: two sections of silver, a section of titanium, and a section of niobium that could create a multi-layered coating stack having individual layers of silver, titanium, niobium or derivatives thereof.

Normally, a cylindrical target is held in a designated position proximate to the vacuum chamber within a distance of the substrate to adequately and efficiently provide the desired coating. Various embodiments of the present invention teach a unique oscillation feature. During sputtering, the target is oscillated in a defined arc about a longitudinal axis. The oscillation enables a larger surface area of each section of the cylindrical target to be consumed during the sputtering process. The utilization of a larger target surface area assists in the prevention of the “race track” pattern of consumption upon the target. Furthermore, the oscillation of the cylindrical target promotes direct contact of more of the target's surface area to the plasma, thus assisting in the prevention of coating materials condensing on the target surface due to overcoating. Therefore, accumulation of sputtering material on the outer surface of the target may be sputtered off when passed through the plasma during oscillation. This self-cleaning feature of an oscillating cylindrical target assembly alleviates the problem of more pronounced consumption of small areas of the target.

Embodiments of the oscillating shielded cylindrical target assembly of the present invention also include a motor assembly for driving the target. The motor assembly includes a motor source that is controlled by an electronic control system. This control system directs and regulates the motor source in oscillating the target during the magnetron sputtering process. The motor source and control system also facilitate the rotation of the target to a position that exposes a different section when another coating material is desired to be sputtered.

In the described embodiment, the oscillating shielded cylindrical target assembly also includes a cylindrical shield that surrounds almost the entire cylindrical target. The shield has a slit opening which is designed to expose a defined surface region of the cylindrical target, such as one of the previously described divided sections. Thus, a single section may be exposed for each coating applied during the sputtering process. Optionally, the shield opening may be covered by a shutter having open and closed positions: open for sputtering, closed to shield the target from overcoating when it is not in use.

Further, the oscillating shielded cylindrical target assembly may also include a magnet assembly that is generally positioned proximate to the cylindrical target in a fixed position. In a preferred embodiment, the magnet assembly comprises a cooling conduit, an optional magnet brace, and magnets of alternating polarity. The magnets create a magnetic field zone or sputtering zone extending along a length of the surface of the cylindrical target and also extending a circumferential distance therearound.

As previously suggested, embodiments of the cylindrical target of the present invention provide multiple sputtering materials on a single cylindrical target. As a result, the need to change targets or provide multiple cylindrical targets for application of two or more coatings is obviated. This translates into ease of operation and a saving of time and expense when manufacturing substrates containing multiple layers of coating materials.

Furthermore, the present invention aids in preventing undesirable consumption, condensation and contamination problems that generally exist with stationary targets. Since the target is oscillated through the sputtering zone, the sputtered coating buildup that may condense upon various parts of the target is removed by passing these parts of the target repeatedly through the sputtering zone thereby creating a self cleaning function. Additionally, the oscillation of the cylindrical target reduces and prevents the creation of racetrack pattern consumption that is commonly formed if the target were held stationary.

Additional objects, features and advantages of the present invention will become apparent from the following description of the preferred embodiments thereof, which description should be taken in conjunction with the accompanying drawings.

### BRIEF DESCRIPTION OF THE DRAWINGS

FIG. 1 is a schematic drawing depicting an oscillating shielded cylindrical target assembly included within a magnetron sputtering system in accordance with an embodiment of the present invention;

FIG. 2 is a schematic drawing depicting an oscillating shielded cylindrical target assembly included within a magnetron sputtering system in accordance with another embodiment of the present invention;

FIG. 3 is a sectional view of an embodiment of an oscillating shielded cylindrical target assembly positioned within a magnetron sputtering system that includes magnets fixed to a cooling conduit;

FIG. 4 is a sectional view depicting an embodiment of an oscillating shielded cylindrical target assembly positioned within a magnetron sputtering system including magnets not fixed to the cooling conduit;

FIG. 5 is a perspective view depicting an embodiment of a multi-sectional cylindrical target;

FIG. 6 is a perspective view depicting an embodiment of a shielded cylindrical target;

FIG. 7 is a perspective, sectional view depicting an embodiment of a shielded cylindrical target assembly that includes a magnet assembly;

FIG. 8 is a sectional view of an embodiment of a cylindrical target assembly that includes a sprocket assembly that interacts with the shield;

FIG. 9 is a sectional view of an embodiment of a cylindrical target assembly that includes a sprocket assembly which interacts with the shutter;

FIG. 10 is a sectional view of an embodiment of a cylindrical target assembly wherein a magnet brace comprises a plurality of rings;

FIG. 11 is a perspective view of an embodiment of a backing and a section plate;

FIG. 12 is a sectional view of an embodiment of a backing which includes target holders and section plates; and

FIG. 13 is a perspective view of an embodiment of a backing.

### DETAILED DESCRIPTION OF THE INVENTION

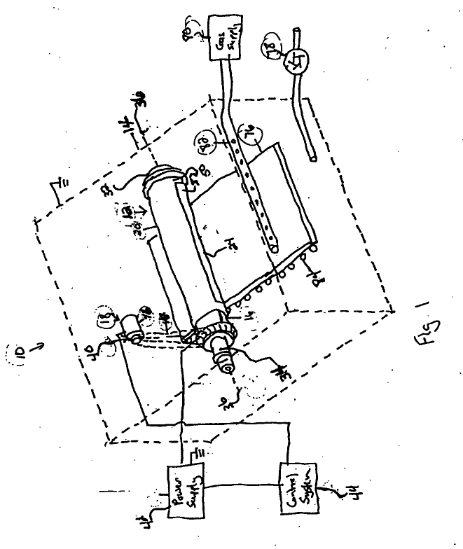

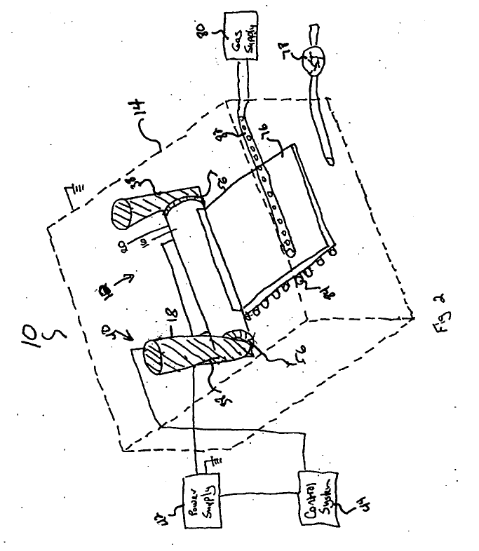

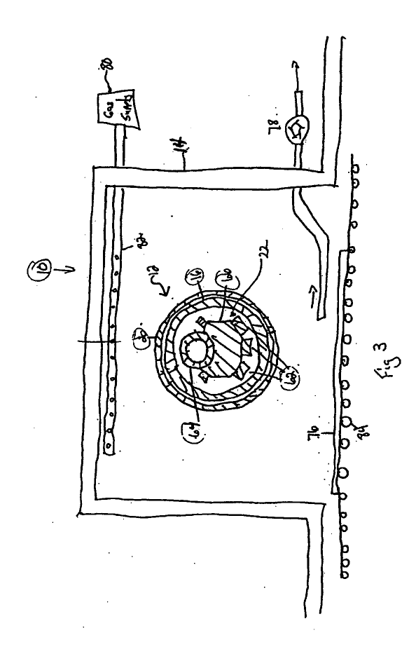

FIGS. 1-4 depict a magnetron sputtering system 10 that includes embodiments of the oscillating cylindrical target assembly 12 of the present invention. The magnetron sputtering process occurs within a controlled atmosphere vacuum chamber 14, which is depicted in phantom lines in FIGS. 1 and 2. Commonly, the oscillating cylindrical target assembly 12 is positioned within the magnetron sputtering system 10 and comprises a cylindrical target 16, a motor assembly 18, an optional shield assembly 20 and an optional magnet assembly 22 (see FIG. 3).

Generally, the cylindrical target 16 is a tubular backing tube formed of electrically conductive material, such as stainless steel, aluminum or any other suitably conductive material. The outer surface of the cylindrical target 16 is normally coated with one or more materials, which are intended to be sputtered onto a workpiece or substrate. This coating of sputterable material is also referred to herein as “target material.”

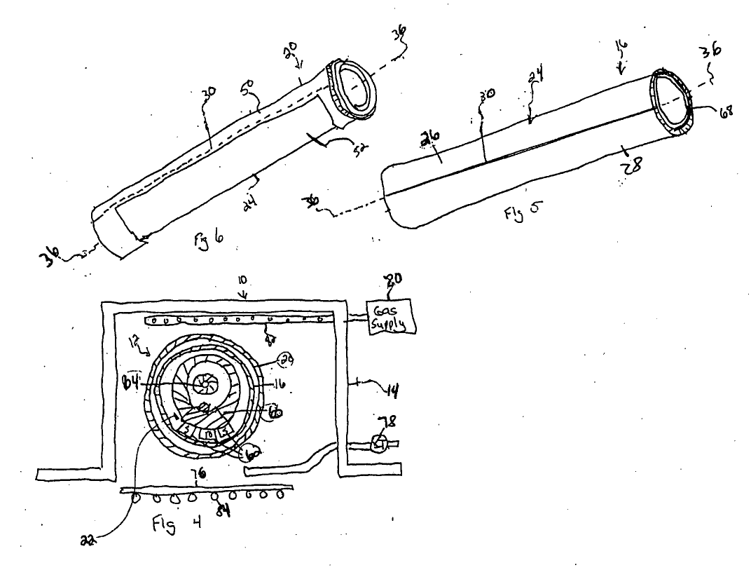

FIG. 5 illustrates one embodiment of the present invention wherein the cylindrical target 16 is composed of a plurality of longitudinally divided sections of differing sputterable materials. The cylindrical target 16 depicted in FIG. 5 includes a surface 24 having two longitudinally divided sections 26 and 28, separated by a dividing line 30. Of course, any number of sections may be used with the present invention. Commonly, the two sections 26, 28 comprise different sputterable materials. FIGS. 5 and 6 show the section dividing line 30 (designated by a solid line in FIG. 5 and a dashed line in FIGS. 6) that separates the two sections. A single cylindrical target 16 may further be configured having more than two sections upon its surface should such configuration be desired. The target material on each section can be formed of any material that is intended to be deposited as part of a coating. Examples of suitable target materials which may be present on such sections of the cylindrical target 16 include, but are not limited to, silver, copper, gold, titanium, zirconium, hafnium, zinc, tin, indium, tantalum, chromium, bismuth, silicon, carbon, nickel, niobium, and stainless steel, NiCr, and alloys or mixtures of these materials. Thus, any desired sputterable material that may be utilized in a magnetron sputtering process may be included as a section of the cylindrical target 16.

The cylindrical target 16 is commonly positioned within a vacuum chamber 14 and held in place by a first support assembly 32 and an optional second support assembly 34 (though the cylindrical target 16 may be held by a single cantilever support at one end of the target, if so desired). The first and second support assemblies 32, 34 secure the cylindrical target 16 in position for sputtering and allow the cylindrical target 16 to oscillate about its longitudinal axis 36. The first and second support assemblies may be comprised of any type of clamp, bracket, frame, fastener or support that keeps the cylindrical target 16 secured in a stationary position and does not affect the oscillation of the cylindrical target 16. A variety of known target support assemblies can be used. Optionally, the motor assembly 18 depicted in FIG. 2 may include a clamping or bracketing device (not shown) that may function as the first support assembly 32 and second support assembly 34. Such a clamping or bracketing device would allow the cylindrical target 16 to be operably adjoined to the motor assembly 18 wherein the cylindrical target 16 is operably adjoined to one or more programmable stepper motors 38. It should be noted that multiple cylindrical targets 16 may be located within the same vacuum chamber 14.

The oscillating cylindrical target assembly 12 further includes a motor assembly 18 connected to the cylindrical target 16. The motor assembly 18 broadly includes a motor source 40, a power source 42, and a control system 44. Examples of motor sources include stepper motors and electric motors, which are typically provided with their own control system. One embodiment of the motor assembly 18 of the present invention, as depicted in FIG. 1, involves the motor source 40, operably adjoined to a power source 42 and control system 44, which includes one or more pulleys 46 and one or more belts 48. The pulleys 46 and belts 48 are operably connected to the cylindrical target 16 so that when activated move the cylindrical target in a back and forth arcing motion. Of course, other types of motor sources 40 and electronic control systems 44 may be used without departing from the spirit or scope of the invention.

FIG. 2 depicts another embodiment of the present invention wherein the motor assembly 18 includes programmable stepper motors 38. The programmable stepper motors. 38 may be configured and/or programmed to optimize the efficient use of the cylindrical target 16 by oscillating the target through the plasma generated in the magnetron sputtering system 10.

The motor assembly 18 may be electronically programmed to produce changes in oscillation speed and arc length, which optimize the sputtering process and the life of the cylindrical target 16. For example, an electronically programmed drive shaft marker may be used to indicate the number of oscillations which have occurred. The program counts a certain number of oscillations, and once a designated number is reached it reverses the target. Alternately, the number of oscillations may be recorded mechanically using a disk which revolves at specified increments per oscillation until a marker is reached which triggers the reversal of the target. The arc length is the partial circumferential extent of the cylindrical target 16 exposed to plasma when oscillated in a back and forth partial rotational movement. For example, a cylindrical target with a circumference of approximately 40 cm may have an arc length of approximately 20 cm if the cylindrical target 16 was oscillated 180° in a back and forth motion. Further, the motor assembly 18 may be programmed to pause at the edges of each divided section 26, 28 of the cylindrical target 16. The pausing may assist in preventing buildup of sputtering material on the edges and may contribute to a more uniform consumption of the target.

The oscillating cylindrical target assembly 12 may also optionally include a cylindrical shield assembly 20, which surrounds the cylindrical target 16. Generally, the cylindrical shield assembly 20 comprises a shield 50, which includes a shield opening 52 and an optional shutter 54 as shown in FIG. 7. In one embodiment of the present invention, the cylindrical shield assembly 20 may be held stationary by the first support assembly 32. Alternatively, as illustrated in FIG. 2, the shield assembly 20 may be operably adjoined to the motor assembly 18 by a shield fastening device 56. The shield fastening device 56 may be any device known in the art, such as clamps, bolts, couplings or other similar fastening means that adequately fastens the shield assembly 20 to the motor assembly 18.

In many of the embodiments of the present invention, the shield assembly 20 extends in length beyond the ends of the cylindrical target surface 24 to ensure complete coverage of the cylindrical target 16 and any support assemblies 32, 34 retaining the target 16. Furthermore, when utilizing cylindrical targets 16 with multiple coating sections 26, 28, the shield assembly 20 preferably extends around the cylindrical target 16 to cover all sections 26,28 of the cylindrical target 16 but one. That is, the shield assembly 20 is preferably configured such that one coating section at a time can be exposed through a shield opening 52 or gap in the shield assembly 20. The section of the cylindrical target 16 left uncovered by the shield assembly 20 may be selected by rotating the target until such selected section is exposed to a region wherein plasma is generated. The shield assembly 20 is preferably made of a material that has a low sputtering yield, such as stainless steel, foils, aluminum or other suitable material.

As previously mentioned, the cylindrical shield assembly 20 includes a shield opening 52. In one embodiment the shield opening, as illustrated in FIG. 6, is of sufficient size to partially expose a single section of sputtering material. The shield opening 52 need not extend along either the full length of the cylindrical shield 50 or the full length of the cylindrical target 16, although either or both may be the case, if so desired. For example, the shield assembly 20 may completely cover the ends of the cylindrical target 16 to at least partially prevent condensation of sputtering materials at each end of the cylindrical target 16.

It should be noted from FIG. 6 that a space exists between the outside surface 24 of the cylindrical target 16 and an inside surface of the cylindrically-shaped shield assembly 20. The cylindrical target 16 and the shield assembly 20 are both preferably, in cross-section, concentric circles that are separated by a distance of preferably less than 3 cm, and more preferably less than 4 mm. A small separation distance is recommended to prevent plasma from forming in the space between the two structures.

As depicted in FIGS. 7-9, the shield assembly 20 can optionally include a separate shutter 54 that may be positioned to conceal the shield opening 52. The shutter 54 may be fastened to the shield 50 by any means that provides efficient covering and uncovering of the shield opening 52. In the alternative, the shutter 54 may be unattached to the shield assembly 20 and held in a stationary position, wherein the shield 50 is rotated to expose the shield opening 52, thus exposing the cylindrical target 16 to the plasma. The opening and closing of the shutter 54 may be controlled by the motor source 40. The motor source 40 may also utilize the same power source 42 and control system 44 as used to oscillate the cylindrical target 16. However, an additional motor source 40, power source 42 and control system 44, other than that used to oscillate the cylindrical target 16 may be used to maneuver the shutter 54.

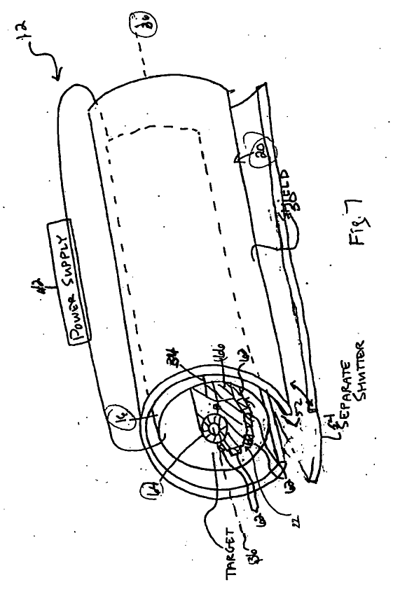

FIGS. 8 and 9 depict an embodiment of the oscillating cylindrical target assembly 12 wherein the shield assembly 20 includes a sprocket system 58 optionally controlled by the motor source 40. In one embodiment the sprocket system 58 may be utilized to rotate either the shield 50 or the shutter 54 by the operation of gears 60 and corresponding teeth 61 located upon the shield 50 and/or the shutter 54. See FIG. 8 for a depiction of the sprocket system 58 applied to the shield 50 and FIG. 9 for a depiction of the sprocket system 58 applied to the shutter 54. Similar to the rest of the shield assembly 20, the shutter 54 may be fabricated from stainless steel, foils, aluminum or other suitable materials.

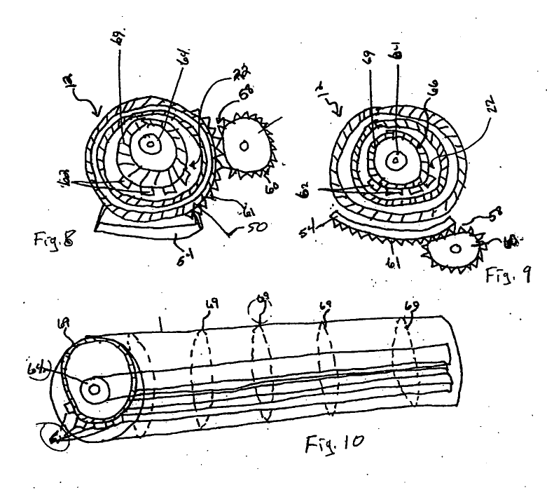

Finally, embodiments of the oscillating cylindrical target assembly 12 of the present invention optionally include a magnet assembly 22. One embodiment of a magnet assembly 22, as shown in FIGS. 3-4 and 7-9, includes magnets 62, an optional cooling conduit 64 and a magnet bracing system 66; all held within the cylindrical target 16 and shield assembly 20. The magnets 62 are positioned along the length of the cylindrical target 16, while extending a partial circumferential, or radial, distance therearound. As previously mentioned the magnets 62 may be attached to a magnet brace system 66. In one embodiment the magnet brace system 66 may be a plurality of cylindrical rings 69 located proximate to the cylindrical target 16 (See FIGS. 8-10). In another embodiment, the magnets 62 are positioned within the cylindrical target 16 by operably coupling the magnet brace system 66 to the coolant conduit 64, also positioned within the cylindrical target 16 (See FIGS. 3 and 7). The magnet brace system 66 may be operably coupled to the cooling conduit 64 by any fastening means, such as welding or clamping.

FIGS. 3-4 and 7-10, depict embodiments of the magnet assembly 22 incorporated within the oscillating cylindrical target assembly 12 wherein elongated magnets 62, of alternate polarity, are positioned within the cylinder target 16 by mounting them to the brace system 66 and positioning the brace assembly adjacent to the cooling conduit 64. As previously suggested, the brace system 66 may be attached to or separated from the cooling conduit 64. Further, it is equally possible to separate the magnets 62 from the cooling conduit 64 such that the magnets 62 remain in a fixed position within the cylindrical target 16. Alternate configurations of the magnets 62 and magnet brace system 66 may be employed such that they are not moved and/or rotated by the oscillation of the cylindrical target 16, thereby positioning them in a fixed position.

As previously mentioned, the magnet assembly 22 may also optionally include a cooling conduit 64. The cooling conduit 64 commonly is one or more pipes or tubes that function to deliver and remove fluid, such as water to and from the oscillating cylindrical target assembly 12. The delivery of cooling fluid assists in the preservation of the overall oscillating cylindrical target assembly 12 by preventing overheating of the various components of the oscillating target assembly 12. The cooling conduit 64 may be provided as part of the oscillating cylindrical target assembly 12 as an independent structure and thereby not rotated by the oscillation of the cylindrical target 16. Alternatively, the cooling conduit 64 may be attached to the motor source 40 or an additional motor source (not shown), which thereby rotates the cooling conduit 64. Rotation of the cooling conduit 64 may further assist in cooling the cylindrical target 16 during the sputtering process.

Generally, a cooling liquid supply and exhaust system (not shown in the figures) positioned outside the vacuum chamber 14 provides coolant to the cooling conduit 64 and exhausts the heated coolant from a space between the outside of the cooling conduit 64 and an interior surface of the cylindrical target 16.

The preparation of the cylindrical targets 16 may be accomplished by utilization of various methods known in the art. For example, the coating materials may be deposited upon the entire outer surface 24 of the cylindrical target 16, or may be deposited upon divided sections, by plasma spraying. For example, the preparation of a cylindrical target 16 including multiple sections 26, 28 generally comprises exposing a defined section of a backing tube 68, normally comprising stainless steel, to a stream of plasma (Such a cylindrical target is depicted in FIG. 5). Next, the sputtering material is injected into the stream. The stream acts to melt the sputtering material and propel or deposit it onto the backing tube 68. This process is repeated using different coating materials until each desired section of the backing is coated. If so desired, all sections of the backing tube 68 except that being plasma sprayed can be covered to isolate deposition of target material on one coating section at a time.

The method of coating a cylindrical target 16 herein has been discussed primarily in the context of plasma spraying. As would be obvious to those skilled in the present art, however, this invention provides apparatuses produced utilizing a wide range of spraying applications. Accordingly, the term plasma spraying is used herein to describe any spraying method that can be used to spray a coating of material on an object. For example, it is to be understood that use herein of the-term plasma spraying includes all of the different forms of spraying (e.g., thermal spraying, water plasma spraying, etc.) that can be used to apply a coating of target material upon the backing tube 68 of a cylindrical target 16 (e.g., a rotary or cylindrical target) or upon any other article that may be coated by spraying methods. Those skilled in this art would be able to immediately apply the present methods and apparatuses to many other spraying methods, all of which would fall within the scope of this invention.

Alternatively, it is noted that the targets may also be produced by utilizing hot press methods. For example, a coating material may be fired in a hot press (high temperature/high pressure) to form the cylindrical target 16 utilized in the present invention. Generally, the coating material is prepared and packed into a hot press mold; then heated to approximately 800-1400° C. and pressed at approximately 50-100 kg/cm² thereby producing a molded coating. Once prepared the molded coating is adhered to a backing tube 68 by methods known in the art thereby forming a cylindrical target 16. Indium tin oxide and titanium dioxide, for example, are utilized in hot press techniques. All techniques utilized to produce sputtering targets can be utilized to produce molded or bent target plates as well.

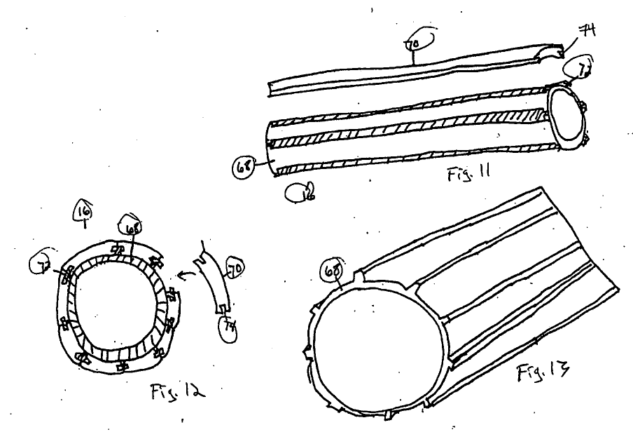

FIGS. 11-13 depict another embodiment of a cylindrical target 16 including multiple coating sections. These embodiments of the present invention may be produced by applying a number of section plates 70 to the backing tube 68. The backing may also include a plurality of attachment devices 72, as shown in FIGS. 11 and 12, for securing each individual section plate 70 to the backing tube 68. The attachment devices 72 preferably extend a short distance from the backing tube 68 to prevent possible problems as the sputtering material of the target erodes away during use. The attachment devices 72 may be any type of securing means, such as clamps, hooks, t-hooks, screws, dovetail or any other suitable device, or any combination thereof, useful for attaching the section plates 70 to the backing tube 68. The section plates 70 may also include notches 74 for operably adjoining the section plates to any and all of the attachment devices 72. Each section plate 70 can provide a different coating material and is sized and shaped to secure to the backing tube 68 with other section plates 70. Of course it may be desirable to provide a plurality of section plates with the same sputtering material and place them non-contiguously on the backing tube 68. The section plates 70 may be prepared by coating a plate backing (not shown) with coating material by plasma spraying or section plates 70 may be prepared by hot pressing techniques. Alternately, the plate may be cast of coating material.

In operation, as seen in FIG. 1, the magnetron sputtering system 10 can be used to deposit one or multiple coatings upon one or more substrates 76 by using the oscillating cylindrical target assembly 12. To prepare for the sputtering process, a vacuum is drawn within the vacuum chamber 14 by an appropriate pumping system 78. One or more gases, such as argon, nitrogen and oxygen, are then provided by a gas supply 80 to the vacuum chamber 14 by a gas delivery system 82, such as a perforated tube, positioned across the vacuum chamber 14. The particular gases utilized depend primarily upon the type of film to be deposited on the substrate 76. Normally, it is preferred to introduce inert gases, such as argon, into the vacuum chamber 14 during the sputtering process unless a reaction with the coating material is desired. Of course, reactive gases, such as oxygen or nitrogen may be introduced into the vacuum chamber 14 during reactive sputtering processes.

The magnetron sputtering system 10, when in operation, produces a plasma within the vacuum chamber 14. The plasma is used to sputter the coating material from the cylindrical target 16 and deposit it onto the substrate 76. Generally the plasma is produced by applying a negative voltage from the power source 42 to the cylindrical target 16 with respect to a positive voltage applied to the vacuum chamber metal frame or applied to some other anode which is usually connected to a ground potential. The application of the positive and negative voltage positions the plasma adjacent to a sputtering zone on the cylindrical target 16. The position of the magnets 62 within the cylindrical target 16 controls the sputtering zone.

In operation of a substrate coating production run, the cylindrical target 16 including multiple sections is rotated by the motor assembly 18 until the section having the desired coating material is positioned over (i.e., adjacent) the shield opening 52. If a shutter 54 is present, the shutter 54 or the shield 50 is rotated to reveal the desired section of coating to be sputtered and thereby expose it to the plasma. Next, a substrate or a plurality of substrates 76 are moved through the vacuum chamber 14 continuously or intermittently, as desired, via a conveyor structure 84 and coated with the coating material of the cylindrical target 16. The coating thickness may be varied by altering the exposure time of each substrate 76 to the plasma generated coating material (e.g., by varying substrate speed and/or sputtering power).

During the sputtering process utilizing the oscillating cylindrical target assembly 12 of the present invention, the cylindrical target 16 is oscillated by the motor assembly 18. The motor assembly 18 operates to oscillate the target in a predetermined defined arc pathway. For example, a cylindrical target 16 with two divided sections 26, 28 (similar to the target depicted in FIG. 5) may be rotationally oscillated approximately 30-270° in a back and forth manner. It is noted that during oscillation of the cylindrical target 16 the longitudinal axis 36 remains in a stationary position. Oscillation of the target enables a dispersed and uniform consumption of the sputtered section and avoids the etched “race track” pattern that commonly results from using stationary targets for magnetron sputtering. The resulting even consumption decreases the likelihood of needing to replace a target before full consumption, thus decreasing costs associated with need for more oscillating cylindrical target assemblies 12. Commonly, during the oscillation of the cylindrical target 16, only a single section of the multi-sectional cylindrical target is exposed at a time. It is also noted that the cylindrical target 16 is preferably oscillated about its longitudinal axis 36, without rotation of the magnets 62 or the shield 50.

Upon complete deposition of a single coating, the cylindrical target 16 may be rotated by the motor assembly 18 to expose the next desired target material section and another coating material may then be applied to the substrate 76. If a shutter 54 and/or shield 50 is used, it is preferred to close the shield opening 52 before rotating the target. This process may be performed repeatedly until the desired number of layers are deposited upon each of the substrates 76.

It is noted that traditionally, multiple targets, each having a single coating material, were necessary to deposit multiple materials on a substrate. Therefore, decreasing the number of targets required to deposit multiple coatings on a substrate reduces significantly the amount of time required to clean and or replace cylindrical targets. Furthermore, the length of the production line for coating substrates is greatly reduced by eliminating chambers for cylindrical targets only having one coating material. Finally, the expense of purchasing additional magnetron sputtering equipment, such as vacuum chambers and other components of magnetron sputtering system is eliminated or greatly reduced.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations, which fall within the spirit and broad scope of the invention.

What is claimed is:

1. An oscillating cylindrical target assembly for use in a magnetron sputtering system comprising:
a cylindrical target including a surface having one or more coating sections and an axis about which the cylindrical target rotationally oscillates;
a magnet assembly including one or more magnets extending along an interior surface of the cylindrical target and extending a circumferential distance therearound; and
a motor assembly operably adjoined to the cylindrical target and adapted to oscillate the cylindrical target.

2. The oscillating cylindrical target assembly of claim 1 wherein the cylindrical target includes a plurality of sections, each section having a single coating material, the coating material of one section differing from the coating material of an adjacent section.

3. The oscillating cylindrical target assembly of claim 1, further including a shield assembly having a shield with an opening designed to expose a portion of the surface of the cylindrical target.

4. The oscillating cylindrical target assembly of claim 3, wherein the shield extends axially along the target surface to cover all sections except for a single exposed section.

5. The oscillating cylindrical target assembly of claim 3 wherein the motor assembly is operably adjoined to the shield assembly for movement of the shield.

6. The oscillating cylindrical target assembly of claim 3, the target assembly further including a sprocket assembly for rotating the shield.

7. The oscillating cylindrical target assembly of claim 3, the shield assembly further including a shutter.

8. The oscillating cylindrical target assembly of claim 7, the target assembly further including a sprocket assembly for opening and closing the shutter.

9. The oscillating cylindrical target assembly of claim 1, wherein the cylindrical target includes a surface containing either 2, 3 or 4 individual sections.

10. The oscillating cylindrical target assembly of claim 1, wherein each coating section includes a single coating material or an oxide or nitride of the coating material selected from the group consisting of silver, copper, gold, titanium, zirconium, hafnium, zinc, tin, indium, bismuth, silicon, carbon, nickel, chromium, NiCr, stainless steel, tantalum and niobium.

11. The oscillating cylindrical target assembly of claim 1, wherein the surface of the cylindrical target includes a section of titanium and a section of niobium.

12. The oscillating cylindrical target assembly of claim 1, wherein the surface contains two sections of silver, a section of titanium, and a section of niobium.

13. The oscillating cylindrical target assembly of claim 1, wherein the motor assembly includes a programmable stepper motor.

14. A method of coating a substrate comprising the steps of:
providing a magnetron sputtering system comprising a cylindrical target assembly including a cylindrical target having a surface with a plurality of sections, each section having a single coating material;
rotating the cylindrical target until a single coating section having a coating material is positioned for exposure to a plasma;
moving a substrate into the magnetron sputtering system; and
exposing the section to a plasma until the substrate is coated with a layer of coating material.

15. The method of coating a substrate of claim 14, further including the step of:
oscillating the cylindrical target while the cylindrical target is exposed to the plasma.

16. The method of coating a substrate of claim 14, further including the steps of:
rotating the cylindrical target until another section having a different coating material is positioned for exposure to a plasma;
exposing the other section to a plasma until the substrate is coated with an additional layer of coating material.

17. A multi-sectional cylindrical target comprising a backing and two or more adjacent sections, each section having a single coating material differing from the coating material of an adjacent section.

18. The multi-sectional cylindrical target of claim 17, wherein the sections are integral to the backing.

19. The multi-sectional cylindrical target of claim 17, wherein the sections are section plates, each section having a single coating material.

20. The multi-sectional cylindrical target of claim 19, wherein the section plates are cast plates of coating material.

21. The multi-sectional cylindrical target of claim 19, wherein the section plates include plate backings covered with a coating material.

22. The multi-sectional cylindrical target of claim 19, wherein the backing includes attachment devices for retaining the section plates.

23. The multi-sectional cylindrical target of claim 22, wherein the section plates include notches for adjoining the section plate with the attaching device.

24. The multi-sectional cylindrical target of claim 22, wherein the attachment device is a clamp.

25. The multi-sectional cylindrical target of claim 24, wherein the section plates include notches for adjoining the section plate with the clamp.

26. The multi-sectional cylindrical target of claim 22, wherein the attachment device is a screw.

27. The multi-sectional cylindrical target of claim 26, wherein the section plates include notches for adjoining the section plate with the screw.

28. A method of preparing a multi-sectional cylindrical target comprising:
administering a coating material to a section of a backing;
rotating the backing to a section not covered with a coating material;
administering a coating material to the uncovered section that is different from the coating material of an adjacent section.

29. The method of claim 28 wherein the steps are repeated until the entire backing is covered with coating materials.
